(19) United States
(12) Patent Application Publication
(10) Pub. No.: US 2019/0252348 A1
(43) Pub. Date: Aug. 15, 2019

(54) SINTERING BONDING METHOD FOR SEMICONDUCTOR DEVICE

(71) Applicants: Hyundai Motor Company, Seoul (KR); Kia Motors Corporation, Seoul (KR)

(72) Inventor: Hiyoshi Michiaki, Kanagawa (JP)

(21) Appl. No.: 16/035,649

(22) Filed: Jul. 15, 2018

(30) Foreign Application Priority Data
Feb. 9, 2018 (KR) 10-2018-0016522

(51) Int. Cl. H01L 23/00; B22F 7/06; B22F 1/00; H01L 21/48

(52) U.S. Cl. CPC H01L 24/83; H01L 2924/10272; B22F 1/0007; H01L 24/32; H01L 21/4821; B22F 2301/10; B22F 2301/255; B22F 2302/25; H01L 2224/83192; H01L 2224/8384; H01L 2224/83203; H01L 2224/29147; H01L 2224/29139; H01L 2924/20107; H01L 2224/32245; H01L 2924/0541; H01L 2924/20108; B22F 7/064

(57) ABSTRACT

Discloses is a method of bonding a semiconductor device, for example, a sintering bonding method for a semiconductor device that can mix pure particles and copper (I) oxide nano particles on a metal substrate. The paste of the present invention may provide low-cost copper paste increasing a copper density as a bonding material when bonding a semiconductor chip continuously used at a high temperature. The copper paste of the present invention may suppress the occurrence of pores or cracks when sintering by heating the copper paste under the reduction atmosphere as saving material costs and implementing an optimum high heat-resistance bonding.

### CROSS-REFERENCE TO RELATED APPLICATION

This application claims under 35 U.S.C. § 119(a) the benefit of priority to Korean Patent Application No. 10-2018-0016522 filed on Feb. 9, 2018, the entire contents of which are incorporated herein by reference.

### TECHNICAL FIELD

The present invention relates to a method of bonding a semiconductor device, and a paste composition used for the same.

### BACKGROUND

Recently, the need for a high-temperature continuous-use semiconductor such as a SiC power module has been increasing, such that there has been an increasing demand for the bonding technology of high heat-resistance and high reliability for bonding a chip of the semiconductor. For example, a copper paste that distributes copper nano particles having heat-resistance has been used a binder.

Generally, as the particle size of metal particles is reduced, the ratio of the number of surface atoms increases, such that the particles become unstable and the bonding between the particles becomes easier. Accordingly, in order to decrease the temperature of the sintering reaction, it may be very effective to miniature the size of the metal particles. However, for pure copper particles, oxidation and cohesion reactions may also be facilitated by the miniaturization and thereby, non-pure copper particles may be used.

For instance, cuprous oxide nano particles, having extremely fine size may be used because they are stable and the handling thereof is easy.

However, the cuprous oxide nano particles may increase cost, and may require sintering under the reduction atmosphere for increasing the sinterability. In addition, because the particle size is extremely fine, the copper density of the paste distributed in solvent may be substantially reduced and the volume shrinkage may be substantially increased. In addition, since the sintering reaction and the shrinking reaction proceed simultaneously, pores, cracks, and the like may be generated inside the sintered bonding layer.

In addition, a large amount of the cuprous oxide nano particle may be required for a dense sintered bonding layer, for example, a high load to the bonding portion, and thus, it is not suitable as bonding material of the semiconductor chip that bonds a large area.

The above information disclosed in this Background section is only for enhancement of understanding of the background of the disclosure and therefore it may contain information that does not form the prior art that is already known in this country to a person of ordinary skill in the art.

### SUMMARY OF THE INVENTION

In preferred aspects, provided herein is a method of bonding a semiconductor device on a substrate. The method may include use of a paste composition as a bonding material or a binder that may be formed by mix pureeing copper particles with copper (I) oxide nano particles such that low-cost copper paste can be used and a copper density may increase. In addition, when the semiconductor chip continuously is used at a high temperature on a metal substrate, the occurrence of pores or cracks may be suppressed when sintering by heating the copper paste under the reduction atmosphere while saving material costs and implementing an optimum high heat-resistance bonding.

In one aspect, provided is a method of bonding a semiconductor chip on a substrate. The method may include depositing on the substrate a paste comprising 1) metal oxide nano particles and 2) elemental metal particles; mounting a semiconductor chip on the copper paste; and sintering the paste of the substrate under the reduction atmosphere. In particular, a size of the elemental metal particles may be greater than a size of the metal oxide nano particles.

The term “metal oxide” as used herein refers to a compound including a metal and oxygen, which may be formed by covalent bond or an ionic bond. In certain embodiments, the metal oxide may include at least one or more of transition metal (M) atoms, and one or more oxygen to form the metal oxide compound. In certain preferred embodiments, the metal oxide may suitably include Cu, Ag, Ni, Co, Pb, Pt, or Au, or particularly Ag or Cu. In certain preferred embodiments, the metal in the metal oxide compound may have an oxidation state of about +1, +2, or +3. In embodiments, the metal oxide compound may be M20, or MO.

The term “elemental metal” as used herein refers to a pure metal component or substantially pure metal component (for example, having a purity of the elemental metal in an amount of about 95 wt %, 96 wt %, 97 wt %, 98 wt %, 99 wt %, 99.5 wt %, 99.9 wt % or greater). In certain embodiments, the elemental metal may include at least one or more of transition metal (M) atoms such as Cu, Ag, Ni, Co, Pb, Pt, or Au. In certain preferred aspect, the elemental metal may be Ag or Cu.

The term “nanoparticle” as used herein refers to a particle having a size (e.g., diameter or the largest diameter) less than about 1 μm, less than about 990 nm, less than about 950 nm, less than about 800 nm, less than about 700 nm, less than about 600 nm, less than about 500 nm, less than about 400 nm, less than about 300 nm, less than about 200 nm, or less than about 100 nm. In certain preferred aspect, the nanoparticle may be formed in sphere or elliptic. In certain preferred embodiments, the nanoparticle may have a diameter (e.g., longest diameter) of about 10 to 100 nm.

The nanoparticle of the invention may include an inorganic oxide. In certain preferred aspects, the metal oxide nanoparticles comprises copper (I) oxide (Cu₂O) nanoparticles, silver (I) oxide (Ag₂O) nano particles, or combinations thereof, and the elemental metal particles comprises pure copper (Cu) particles, pure silver (Ag) particles or combinations thereof.

The sintering may suitably include pressuring and heating the paste.

The elemental metal particles may have the same size or at least two or more different sizes. The size of the larger particle of the elemental metal particles may be different by about 10% of the smaller particle size, by about 20% of the smaller particle size, by about 30% of the smaller particle size, by about 40% of the smaller particle size, by about 50% of the smaller particle size, by about 60% of the smaller particle size, by about 70% of the smaller particle size, by about 80% of the smaller particle size, by about 90% of the smaller particle size, or by about 100% of the smaller particle size. The size of the larger particle of the elemental metal particles may be different by about 1.5 fold of the smaller particle size, by about 2 fold of the smaller particle size, by about 3 fold of the smaller particle size, by about 4 fold of the smaller particle size, by about 5 fold of the smaller particle size, by about 6 fold of the smaller particle size, by about 7 fold of the smaller particle size, by about 8 fold of the smaller particle size, by about 9 fold of the smaller particle size, or by about 10 fold of the smaller particle size.

The size of each particle may be measured by the maximum cross-sectional dimension, for example, the maximum cross-sectional diameter of the spherical or oval particles. Further, the size of particles may be measured by average or mean size of the cross-sectional dimension, for example, of the spherical or oval particles.

The elemental metal particles and the metal oxide particles may be different by about 1.5 fold of the metal oxide particle size, by about 5 fold of the metal oxide particle size, by about 10 fold of the metal oxide particle size, by about 15 fold of the metal oxide particle size, or by about 20 fold of the metal oxide particle size.

The paste may suitably include the copper (I) oxide nano particles having the particle size of about 10 nm to 100 nm and the pure copper particles having the particle size of about 0.10 μm to 0.15 μm. Preferably, the paste may include the copper (I) oxide nano particles having the particle size of about 10 nm to 100 nm, the pure copper particles having the particle size of about 0.10 μm to 0.15 μm, and the pure copper particles having the particle size of about 1.0 μm to 10.0 μm.

Alternatively, the copper paste may suitably include the copper (I) oxide nano particles having the particle size of about 30 nm to 60 nm and the pure copper particles having the particle size of about 0.10 μm to 0.15 μm. Preferably, the paste may include the copper (I) oxide nano particles having the particle size of about 30 nm to 60 nm, the pure copper particles having the particle size of about 0.10 μm to 0.15 μm, and the pure copper particles having the particle size of about 1.0 μm 10.0 μm.

The paste may include an amount of about 0.1 weight %˜5.0 weight % the copper (I) oxide nano particles based on the total weight of the paste. Preferably, the paste may include the pure copper particles in an amount of about 87.6 to 91.6 weight %, the copper (I) oxide nano particles in an amount of about 0.1 to 5.0 weight %, and a solvent in an amount of about 6.0 to 10.0 weight %, all the weight % are based on the total weight of the paste.

Preferably, the sintering may include heating the paste at the temperature of about 250 to 300° C.

The substrate on which the semiconductor chip is bonded and mounted may suitably be a metal substrate.

In another aspect, provided is a paste composition that may include copper (I) oxide (Cu₂O) nano particles; copper (Cu) particles; and a solvent. In particular, a size of the copper (Cu) particles may be greater than a size of the copper (I) oxide nano particles.

Preferably, the paste composition comprises the copper (I) oxide nano particles having the size of about 10 nm to 100 nm and the pure copper particles having the size of about 0.10 μm to 0.15 μm. The paste composition may further include the pure copper particles having the size of about 1.0 μm to 10.0 μm.

Alternatively, the paste composition may suitably include the copper (I) oxide nano particles having the particle size of about 30 nm to 60 nm and the pure copper particles having the particle size of about 0.10 μm to 0.15 μm. Preferably, the paste composition may further include the pure copper particles having the particle size of about 1.0 μm 10.0 μm.

The paste composition may suitably include an amount of about 0.1 weight % to 5.0 weight % of the copper (I) oxide nano particles based on the total weight of the paste. Preferably, the paste composition comprises an amount of about 87.6 to 91.6 weight % of the pure copper particles, an amount of about 0.1 to 5.0 weight % of the copper (I) oxide nano particles, and an amount of about 6.0 to 10.0 weight % of the solvent, all the weight % are based on the total weight of the paste.

According to the various aspects of the present invention, the pure copper particles and the copper (I) oxide nano particles having different particle sizes may be mixed to produce the low-cost copper paste as increasing the copper density as bonding material. As such, occurrence of pores or cracks may be suppressed when sintering by heating the copper paste under the reduction atmosphere while saving material costs of the copper paste.

Other aspects and preferred embodiments of the disclosure are discussed infra.

The above and other features of the disclosure are discussed infra.

### BRIEF DESCRIPTION OF THE DRAWINGS

The above and other features of the present disclosure will now be described in detail with reference to certain exemplary embodiments thereof illustrated the accompanying drawings which are given hereinbelow by way of illustration only, and thus are not limitative of the present disclosure, and wherein:

FIG. 1 schematically shows an exemplary method of bonding an exemplary semiconductor device in accordance with an exemplary embodiment of the present invention.

FIG. 2 is a schematic flowchart illustrating an exemplary method of bonding an exemplary semiconductor device in accordance with an exemplary embodiment of the present invention.

FIG. 3 is a graph illustrating the experimental result that sinters copper paste in the same condition by varying only a temperature condition under 100% hydrogen atmosphere and atmospheric pressure in accordance with an exemplary embodiment of the present invention.

It should be understood that the appended drawings are not necessarily to scale, presenting a somewhat simplified representation of various preferred features illustrative of the basic principles of the disclosure. The specific design features of the present disclosure as disclosed herein, including, for example, specific dimensions, orientations, locations, and shapes will be determined in part by the particular intended application and use environment.

In the figures, reference numbers refer to the same or equivalent parts of the present disclosure throughout the several figures of the drawing.

### DETAILED DESCRIPTION

Hereinafter reference will now be made in detail to various embodiments of the present disclosure, examples of which are illustrated in the accompanying drawings and described below. While the disclosure will be described in conjunction with exemplary embodiments, it will be understood that present description is not intended to limit the disclosure to those exemplary embodiments. On the contrary, the disclosure is intended to cover not only the exemplary embodiments, but also various alternatives, modifications, equivalents and other embodiments, which may be included within the spirit and scope of the disclosure as defined by the appended claims.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprise”, “include”, “have”, etc. when used in this specification, specify the presence of stated features, regions, integers, steps, operations, elements and/or components but do not preclude the presence or addition of one or more other features, regions, integers, steps, operations, elements, components, and/or combinations thereof.

Further, unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Hereinafter, exemplary embodiments will be described so that those skilled in the art can easily practice the present disclosure.

The present invention relates to a method that bonds a semiconductor chip, which may be continuously used at a high temperature, such as a SiC power module on a metal substrate. The method include suing a copper paste (“paste”) including pure copper particles and copper (I) oxide nano particles (cuprous oxide nano particles) to increase a copper density as bonding material when bonding the semiconductor chip continuously used at the high temperature on the metal substrate. As such, the occurrence of pores or cracks may be suppressed when sintering the paste by heating the copper paste under the reduction atmosphere. The paste (copper paste) of the present invention may reduce costs of the copper paste as implementing an optimum high heat-resistance bonding.

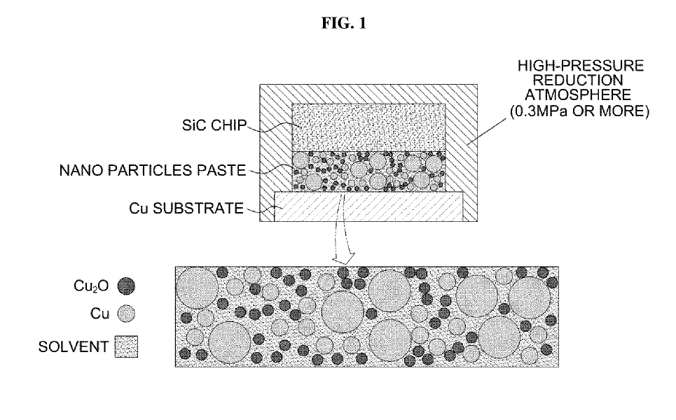

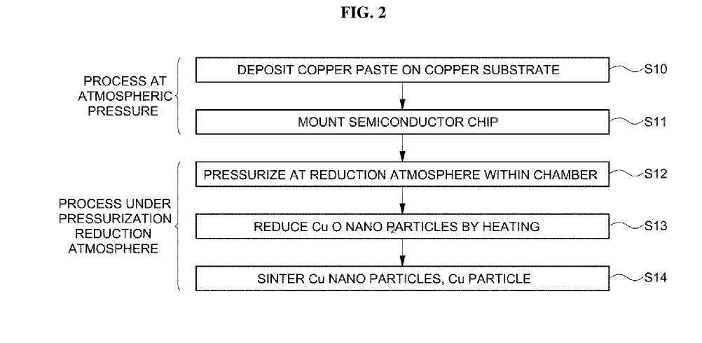

FIG. 1 shows an exemplary sintering bonding method for a semiconductor device in accordance with the present invention, and FIG. 2 is a flowchart illustrating an exemplary sintering bonding method for the semiconductor device in accordance with an exemplary embodiment of the present invention.

As illustrated in FIGS. 1 and 2, a copper paste including copper (I) oxide (Cu₂O) nano particles with pure copper (Cu) particles may be deposited on a metal substrate (S10).

The copper paste may be formed by mixing the copper (I) oxide nano particles, the pure copper particles, and solvent; the pure copper particles can use one kind or two kinds of the pure copper particles having a greater particle size than the copper (I) oxide nano particles; and the copper (I) oxide nano particles use the copper (I) oxide nano particles having a smaller particle size than the pure copper particles.

In addition, the pure copper particles may suitably include one or more kinds of the pure copper micro-particles based on the size of the particles.

For example, when one kind of the pure copper particles is used, the pure copper micro-particles may have the particle size of about 0.10 μm˜to 0.15 μm. When two kinds of the pure copper particles is used, first pure copper micro-particles may have a relatively small particle size of about 0.10 μm to 0.15 μm and second pure copper micro-particles may have particle size of about 1.0 μm to 10.0 μm.

The copper (I) oxide nano particles may suitably have the size of about 100 nm or less, or preferably, the particle size of about 10 nm to 100 nm. Preferably, the copper (I) oxide nano particles may have the particle size of about 30 nm to 60 nm.

The copper (I) oxide nano particles having the size much less than the pure copper particles with the pure copper particles may be mixed to form the copper paste, thus increasing the copper density of the copper paste. In addition, when two kinds of the pure copper particles based on the size of the particles to use together with the copper (I) oxide nano particles are mixed, the copper density of the copper paste may be effectively increased.

The copper paste may include an amount of about 0.1 to 5.0 weight % filled with the copper (I) oxide nano particles based on the total weight of the copper paste, and include the remainder filled with the pure copper particles and the solvent.

Preferably, the copper paste may include the pure copper (Cu) particles in an amount of about 87.6 to 91.6 weight %, the copper (I) oxide (Cu₂O) nano particles in an amount of about 0.1 to 5.0 weight %, and the solvent in an amount of about 6.0 to 10.0 weight %.

For example, the copper paste may include an amount of about 87.6 to 91.6 weight % of the pure copper (Cu) particles having the particle size of about 0.1 μm to 10.0 μm, an amount of about 0.1˜5.0 weight % of the copper (I) oxide (Cu₂O) nano particles having the particle size of about 30 nm to 60 nm, and an amount of about the solvent 6.0 to 10.0 weight %. All the weight % are based on the total weight of the copper paste.

In addition, the copper paste may include an amount of about 43.8 to 45.8 weight % of the pure copper (Cu) particles having the particle size of about 1.0 μm to 10.0 μm, an amount of about 43.8˜45.8 weight % of the pure copper (Cu) particles having the particle size of about 0.10 μm to 0.15 μm, an amount of about 0.1˜5.0 weight % of the copper (I) oxide (Cu₂O) nano particles having the particle size of about 30 nm to 60 nm, and an amount of about 6.0 to 10.0 weight % of the solvent.

The solvent may not be particularly limited, and a solvent for suspending particles (e.g., metal oxide particles) as used in the related art may be used without limitation. The solvent may be an organic solvent. The solvent may be a polar solvent. The solvent may include a glycol. The solvent may include an alcohol. The solvent may include α-Terpineol and the like.

The copper paste as described herein may be prepared at reduced cost compared to a conventional copper paste including an expensive copper (I) oxide nano particles. Moreover, the copper paste as described herein may have a greater density of copper (Cu) contents than a conventional copper paste including only the pure copper particles having a large particle size. As results, occurrence of pores or cracks may be suppressed and the dense bonding material of high density of copper may be obtained for sintering, such that an optimum high heat-resistance bonding may be obtained when bonding the semiconductor chip on the metal substrate.

In addition, the copper (I) oxide nano particles and the pure cooper particles having different particle sizes may be mixed by an optimum mixture, thus effectively increasing the copper density of the copper paste may be obtained as reducing the content amount of the solvent, and forming a low-cost copper paste increasing the copper density.

For example, when using the copper paste of high density having a high copper density, the copper density may be highly maintained after the sintering bonding, and thereby a sintered bonding layer (copper paste) between the metal substrate and the semiconductor chip may be densely formed without pores or cracks, and the bonding strength of the sintered bonding layer is increased.

In addition, the copper (I) oxide nano particles may be formed by a thermal plasma method, and the metal substrate may use a copper substrate, or the like.

General manufacturing methods (liquid phase method) of the copper (I) oxide nano particles may be a hydrolysis method, a hydrothermal synthesis method, a liquid-phase reduction method, a crystallization method, and the like, and these manufacturing methods have the disadvantages in that the particles are likely to be contaminated during the production of the particles. For example, the particles may tend to stick to each other, and the particles may be largely varied in particle size and shape and easily oxidized.

When manufacturing the copper (I) oxide nano particles using the thermal plasma method, the particle pollution may be reduced, the particle size and the shape thereof may be uniform, and the price may be reduced cheap. In addition, the dispersibility in the solvent may be improved and the mixed dispersibility of the two kinds of particles may be improved when forming the copper paste.

In addition, the semiconductor chip may have the surface on the side bonded to the metal substrate composed of a Ni layer, and an Au thin film layer or an Ag thin film layer, the copper (I) oxide nano particles may be substantially and well bonded to the Ni layer of the semiconductor chip by the reduction reaction, and the interface thereof may be strengthened.

Then, the semiconductor chip may be mounted on the metal substrate depositing the copper paste (S11), and the metal substrate mounting the semiconductor chip may be inserted into a chamber forming the reduction atmosphere and pressurized under the reduction atmosphere (S12).

In this time, since the copper density of the copper paste is high, although the pressure within the chamber is maintained in the non-load state (i.e., atmospheric pressure) that may not apply separate pressure, the copper paste may be densely sintered without causing pores or cracks. Preferably, the pressure of about 0.3 MPa to 1.0 MPa may be applied within the chamber in order to promote effective reduction reaction.

Then, by heating the copper paste at the temperature of about 250 to 300° C. under the reduction atmosphere within the chamber to reduce the copper (I) oxide nano particles (S13), the copper nano particles of the copper (I) oxide nano particles and the pure copper particles may be sintered (S14).

By sintering the reduced copper nano particles of the copper (I) oxide nano particles, or the copper nano particles and the pure copper particles that are reduced, the metal substrate and the semiconductor chip may be bonded.

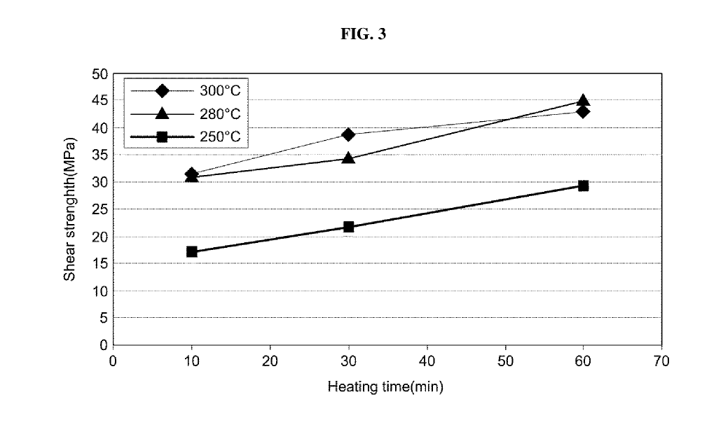

And, as illustrated in FIG. 3, the copper paste may be heated at the temperature of about 280 to 300° C. in order to maximize the shearing strength. FIG. 3 is a graph illustrating the experimental result from an exemplary sintering the copper paste in the same condition satisfying the forming condition by varying only temperature condition under the hydrogen 100% atmosphere and atmospheric pressure.

As described above, in case of performing the sintering bonding for the copper paste under the reduction atmosphere at the atmospheric pressure or more without applying separate additional load thereto, there are the following advantages.

1. It is possible to arrange in plural the semiconductor chip on a rack within the high-temperature chamber providing the reduction atmosphere to sinter all at once to be bonded to the metal substrate, thus ensuring high productivity.

2. It is unnecessary to perform a preliminary process such as paste drying, and the sintering bonding process can be performed within 30 minutes.

3. It is unnecessary to use a press machine for applying an additional load to the copper paste, and to sinter the copper paste using a heater attached to the press machine for heating the copper paste. Upon sintering using the heater, the productivity of the semiconductor device is much reduced and the cost also increases.

4. In case of using the conventional press machine, there is a high possibility that the surface of the semiconductor chip is damaged due to fine cracks, and the like in the process of applying an additional load to the copper paste, such that it is difficult to maintain a high quality and a deviation occurs in pressure distribution in the semiconductor chip. However, in the present invention, it is possible to prevent the deterioration of the quality and the performance due to using the press machine while securing the bonding strength at the same level as that in the case of using the press machine.

5. The solvent in the central portion of the semiconductor chip may be discharged to the outside under the reduction atmosphere at a slightly higher pressure than the atmospheric pressure, which is suitable for sintering bonding of a large area semiconductor chip.

In addition, in the present invention, a silver paste may be deposited instead of the copper paste on the metal substrate and the semiconductor chip may be mounted on the silver paste to perform sintering bonding.

In addition, the silver paste may include silver (1) oxide (Ag₂O) nano particles and pure silver (Ag) particles having a greater particle size than the silver (1) oxide (Ag₂O) nano particles. For instance, the characteristics of the content amount, the particle size, and the like the silver (1) oxide (Ag₂O) nano particles and the pure silver (Ag) particles can be the same as the characteristics of the content amount, the particle size, and the like copper (I) oxide (Cu₂O) nano particles and the pure copper (Cu) particles.

Meanwhile, Table 1 below illustrates the comparison of the shearing strength of the sintered bonding layer (the sintered copper paste) according to the sintering process of the case (A) that produces the copper paste by mixing the two kinds of the pure copper particles and the copper (I) oxide nano particles having different particle sizes and the case (B) that produces the copper paste by mixing two kinds of the pure copper particles having different particle sizes.

TABLE 1

| | Particle Mixing Ratio | | | Shearing |
|---|---|---|---|---|
| | Cu₂O | Cu | Cu | Strength |
| Paste | Φ30 nm | Φ130 nm | Φ1 μm | (MPa) |
| A | 1 | 10 | 10 | 17.4-21.0 |
| B | 0 | 10 | 10 | 2.3-3.3 |

Φ: particle size

As illustrated in Table 1, it was confirmed that the shearing strength of the copper paste (A) produced by mixing the two kinds of the pure copper particles and the copper (I) oxide nano particles was much higher than the copper paste (B) produced by mixing the two kinds of the pure copper particles.

In addition, Table 2 below illustrates the comparison of the shearing strength of the sintered bonding layer (the sintered copper paste) according to the sintering process of the copper pastes (A′, C) that produce the copper paste by mixing the two kinds of the pure copper particles and the copper (I) oxide nano particles having different particle size and produce by varying the mixing ratio (content amount) of the copper (I) oxide nano particles. In this time, the sintering process was performed by heating at a temperature of about 300° C. for 60 minutes.

TABLE 2

| | Particle Mixing Ratio | | | Shearing |
|---|---|---|---|---|
| | Cu₂O | Cu | Cu | Strength |
| Paste | Φ30 nm | Φ130 nm | Φ1 μm | (MPa) |
| A′ | 1 | 10 | 10 | 6.6-8.9 |
| C | 0.1 | 10 | 10 | 30 |

Φ: particle size

Sintering experimental result (300° C.×60 min)

As illustrated in Table 2, the shearing strength of the copper paste (A′) that the mixing ratio of the copper (I) oxide nano particles was large was much larger than the copper paste (C) that the mixing ratio of the copper (I) oxide nano particles was relatively small.

In addition, upon producing the copper paste, the shearing strength of the sintered bonding layer (the sintered bonding layer between the metal substrate and the semiconductor chip) maximized according to the sintering of the copper paste by the content amount optimization of the copper (I) oxide nano particles.

In this time, the copper paste (A′) used the copper paste formed by mixing the pure copper particles 43.8 weight % having the particle size of 0.13 μm, the pure copper particles 43.8 weight % having the particle size of 1 μm, the copper (I) oxide nano particles 4.4 weight % having the particle size of 30 nm, and the solvent 8.0 weight %.

For reference, the copper paste (A′) in Table 2 has the same particle mixing ratio as the copper paste (A) in Table 1, but there is a difference in the shearing strength due to different temperature and time conditions, etc. during the sintering process.

Having described the various exemplary embodiments of the present invention in detail with reference to the drawings, the present invention is not limited to the above-described embodiments, and various modifications can be made without departing from the technical scope of the present invention.

What is claimed is:

1. A method of bonding a semiconductor chip on a substrate, comprising:
depositing on the substrate a paste comprising 1) a metal oxide nano particles and 2) elemental metal particles, wherein a size of the elemental metal particles is greater than a size of the metal oxide nano particles;
mounting the semiconductor chip on the paste; and
sintering the paste of the substrate under the reduction atmosphere to fix the semiconductor chip to the substrate.

2. The method of claim 1, wherein the sintering comprises pressuring and heating the paste.

3. The method of claim 1, wherein the metal oxide nano particles comprises copper (I) oxide (Cu₂O) nano particles, silver (I) oxide (Ag₂O) nano particles, or combinations thereof, and the elemental metal particles comprises pure copper (Cu) particles, pure silver (Ag) particles or combinations thereof.

4. The method of claim 3,
wherein the paste comprises the copper (I) oxide nano particles having the size of about 10 nm to 100 nm and the pure copper particles having the size of about 0.10 μm to 0.15 μm.

5. The method of claim 3,
wherein the paste comprises the copper (I) oxide nano particles having the size of about 10 nm to 100 nm, the pure copper particles having the size of about 0.10 μm to 0.15 μm, and the pure copper particles having the size of about 1.0 μm to 10.0 μm.

6. The method of claim 3,
wherein the paste comprises an amount of about 0.1 weight % to 5.0 weight % of the copper (I) oxide nano particles based on the total weight of the paste.

7. The method of claim 3,
wherein the paste is formed by mixing the pure copper particles in an amount of about 87.6 to 91.6 weight %, the copper (I) oxide nano particles in an amount of about 0.1 to 5.0 weight %, and a solvent in an amount of about 6.0 to 10.0 weight %, based on the total weight of the paste.

8. The method of claim 1,
wherein the sintering comprises heating the paste at the temperature of about 250 to 300° C.

9. The method of claim 3,
wherein the paste comprises the copper (I) oxide nano particles having the size of about 30 nm to 60 nm and the pure copper particles having the size of about 0.10 μm to 0.15 μm.

10. The method of claim 3,
wherein the paste comprises the copper (I) oxide nano particles having the size of about 30 nm to 60 nm, the pure copper particles having the size of about 0.10 μm to 0.15 μm, and the pure copper particles having the size of 1.0 μm to 10.0 μm.

11. The method of claim 1, wherein the substrate is a metal substrate.

12. A paste composition comprising,
copper (I) oxide (Cu₂O) nano particles;
copper (Cu) particles; and
a solvent,
wherein a size of the copper (Cu) particles is greater than a size of the copper (I) oxide nano particles.

13. The paste composition of claim 12, wherein paste composition comprises the copper (I) oxide nano particles having the size of about 10 nm to 100 nm and the pure copper particles having the size of about 0.10 μm to 0.15 μm.

14. The paste composition of claim 13, wherein the paste composition further comprises the pure copper particles having the size of about 1.0 μm to 10.0 μm.

15. The paste composition of claim 12, wherein the pastecomprises the copper (I) oxide nano particles having the particle size of about 30 nm to 60 nm and the pure copper particles having the particle size of about 0.10 μm to 0.15 μm.

16. The paste composition of claim 15, wherein the paste may further include the pure copper particles having the particle size of about 1.0 μm 10.0 μm.

17. The paste composition of claim 12, wherein the paste composition comprises an amount of about 0.1 weight % to 5.0 weight % of the copper (I) oxide nano particles based on the total weight of the paste.

18. The paste composition of claim 12, wherein the paste composition comprises an amount of about 87.6 to 91.6 weight % of the pure copper particles, an amount of about 0.1 to 5.0 weight % of the copper (I) oxide nano particles, and an amount of about 6.0 to 10.0 weight % of the solvent, all the weight % are based on the total weight of the paste.
